(19) United States
(12) Patent Application Publication
(10) Pub. No.: US 2026/0253633 A1
(43) Pub. Date: Aug. 27, 2026

(54) MEMORY DEVICE PERFORMING GATHER OPERATION OR SCATTER OPERATION AND METHOD OF OPERATING THE SAME

(71) Applicant: SEOUL NATIONAL UNIVERSITY R&DB FOUNDATION, Seoul (KR)

(72) Inventors: Jinho LEE, Seoul (KR); Changmin SHIN, Seoul (KR); Taehee KWON, Hwaseong-si (KR); Jae Hyung JU, Seoul (KR); Yeonkyu CHOI, Hwaseong-si (KR); Jaeyong SONG, Gwangmyeong-si (KR)

(21) Appl. No.: 19/314,816

(22) Filed: Aug. 29, 2025

(30) Foreign Application Priority Data
Feb. 26, 2025 (KR) 10-2025-0024717

(51) Int. Cl. G11C 11/4096; G11C 11/408; G11C 11/4093

(52) U.S. Cl. CPC G11C 11/4096; G11C 11/4087; G11C 11/4093

(57) ABSTRACT

A memory device according to an embodiment is configured to perform a gather operation or a scatter operation. The memory device includes at least one memory bank, and the memory bank comprises: a cell array including a plurality of DRAM memory cells; an offset buffer in which read target addresses or write target addresses transmitted from a host are stored; a data buffer in which read data read from the cell array according to the read target addresses or write data to be stored at the write target addresses are stored; and a controller configured to execute a read command or a write command for the cell array when a number of read target addresses or a number of write target addresses in the offset buffer corresponds to a threshold.

### CROSS-REFERENCE TO RELATED APPLICATION

This application is based on and claims priority under 35 U.S.C. §119 to Korean Patent Application No. 10-2025-0024717, filed on Feb. 26, 2025, in the Korean Intellectual Property Office, the disclosure of which is incorporated by reference herein in its entirety.

### BACKGROUND

The present invention relates to a memory device performing a gather operation or a scatter operation and a method of operating the same.

### SUMMARY

Recently, due to the rapid development of parallel architectures, modern computing systems have faced limitations imposed by memory. A widely adopted approach to alleviate memory bandwidth bottlenecks is to support various types of functions in memory (FIM), such as GEMV (General Matrix Vector multiplication), reduction, and vector operations. Although various computing functions have been considered as FIM candidates, they involve increased cost.

Due to differences in process technology, the cost of arithmetic units is also considerably high. For example, a MAC (Multiply-Accumulate) unit is known to occupy more than half of the area in commercial FIM products. Such area overhead is difficult to accept in the DRAM industry, where cost sensitivity is extremely high. In addition, industry standards such as DDR require multi-chip ranks, wherein words are interleaved across multiple chips. This may limit arithmetic operations inside each DRAM chip unless the associated conversion overhead is minimal.

The present invention addresses these issues by proposing a new architecture for intelligent memory. In particular, while conventional DRAM technology requires data to be read in 64-byte units during memory access in a computer system, the present invention proposes a technique for gathering and reading smaller units of data.

In this regard, the problems of the conventional technology will be examined in more detail.

FIG. 1 is a diagram for explaining problems of data read or write operations in conventional DRAM.

In DRAM, a gather operation refers to an operation of reading data from multiple non-contiguous memory addresses, while a scatter operation refers to an operation of writing data to non-contiguous locations in memory.

In FIG. 1, the gather operation is illustrated on the left, and the scatter operation is illustrated on the right.

For example, a memory chip may include eight different memory banks (Bank 0 to Bank 7). Each memory bank performs an operation of gathering or scattering small amounts of data. In such a case, the memory controller of the host transmits the address of the desired data and a command (read/write) to the DRAM memory through the command/address bus. In the gather operation, a read command is transmitted; in the scatter operation, a write command is transmitted. Apart from that, both operations perform read or write on non-contiguous addresses in the memory.

According to the gather operation, the DRAM transmits data to the host through a data bus, but the data transfer size from the DRAM is typically 64 bytes, which is much larger than the actual required data of 8 bytes. Therefore, in order to read eight pieces of 8-byte data located at random addresses in the memory cell array, the read command and target address must be transmitted to each memory bank, resulting in eight separate read commands and addresses, and performing eight 64-byte read operations. Similarly, in the scatter operation, eight write commands and addresses are required, resulting in eight 64-byte write operations, leading to redundant actions.

The present invention aims to overcome such inefficiencies of the gather and scatter operations in conventional DRAM technology.

### Prior Art Document

Korean Unexamined Patent Publication No. 10-2019-0113430 (Title: Memory Controller and Method of Operating the Same)

### Problem to be Solved by the Invention

The present invention is intended to solve the above-described problems, and an object of the present invention is to provide a memory device and a method of operating the same that can reduce the number of communications with a host when performing gather or scatter operations for each memory bank.

However, the technical problem to be achieved by the present embodiment is not limited to the above-mentioned problem, and other technical problems may also exist.

As a technical means for solving the above-described problem, a memory device performing a gather operation or a scatter operation according to an embodiment of the present invention includes at least one memory bank, wherein the memory bank comprises: a cell array including a plurality of DRAM memory cells; an offset buffer in which read target addresses or write target addresses transmitted from a host are stored; a data buffer in which read data read from the cell array according to the read target addresses or write data to be stored at the write target addresses is stored; and a controller configured to execute a read command or a write command for the cell array when a number of read target addresses or a number of write target addresses in the offset buffer corresponds to a threshold condition.

According to another embodiment of the present invention, a method of operating a memory device that performs a gather operation includes: storing read target addresses transmitted from a host in an offset buffer of the memory device; executing, by a controller of the memory device, a read command for the cell array of the memory device based on the read target addresses in response to the read command from the host, when the number of the read target addresses reaches a threshold; storing the read data, corresponding to the number of the threshold, read from the cell array in a data buffer of the memory device; and transmitting the number of read data stored in the data buffer to the host.

According to another embodiment of the present invention, a method of operating a memory device that performs a scatter operation includes: storing write target addresses transmitted from a host in an offset buffer of the memory device, and storing write target data transmitted from the host in a data buffer of the memory device; and executing, by a controller of the memory device, a write command for the cell array of the memory device based on the number of write target addresses and a number of write target data when the number of the write target addresses and write target data corresponds to the threshold, in response to a write command from the host.

According to any one of the above-described means for solving the problem of the present invention, it is possible to reduce the number of accesses to the host memory during the execution of gather or scatter operations. Accordingly, the memory bandwidth between the host and the memory can be significantly increased, which theoretically leads to up to four times performance improvement. Additionally, since data movement occurs only inside the memory, the data transfer distance is shortened, which also contributes to reducing system power consumption.

### BRIEF DESCRIPTION OF THE DRAWINGS

FIG. 1 is a diagram illustrating a problem in a data read or write process in conventional DRAM.

FIG. 2 is a diagram illustrating a configuration of a memory device according to an embodiment of the present invention.

FIG. 3 is a diagram illustrating a gather operation and a scatter operation of a memory device according to an embodiment of the present invention.

FIG. 4 is a flowchart illustrating a method of operating a memory device to perform a gather operation according to an embodiment of the present invention.

FIG. 5 is a flowchart illustrating a method of operating a memory device to perform a scatter operation according to an embodiment of the present invention.

### DETAILED DESCRIPTION

Hereinafter, embodiments of the present invention will be described in detail with reference to the accompanying drawings so that those skilled in the art to which the present invention pertains can easily carry out the invention. However, the present invention may be implemented in various different forms and is not limited to the embodiments described herein. In the drawings, components irrelevant to the description are omitted for clarity of the invention, and similar reference numerals are assigned to similar components throughout the specification.

Throughout the specification, when a part is described as being "connected" to another part, this includes not only a “direct connection” but also an “electrical connection” via another component in between. Also, when a part is described as "including" a component, it does not exclude other components unless otherwise specified, but rather may further include additional components.

In the present specification, the term “unit” refers to a unit implemented by hardware, a unit implemented by software, or a unit implemented using both hardware and software. A single unit may be implemented using two or more pieces of hardware, and two or more units may be implemented using a single piece of hardware. Meanwhile, the term “~ unit” is not limited to either software or hardware. A “~ unit” may be configured to reside on an addressable storage medium or to be executed by one or more processors. Accordingly, by way of example, a “~ unit” may include software components, object-oriented software components, class components, task components, as well as processes, functions, attributes, procedures, subroutines, program code segments, drivers, firmware, microcode, circuits, data, databases, data structures, tables, arrays, and variables. The functions provided in the components or “~ units” may be combined into a smaller number of components or “~ units,” or may be divided into additional components or “~ units.” Furthermore, the components and “~ units” may be implemented to be executed by one or more CPUs within a device.

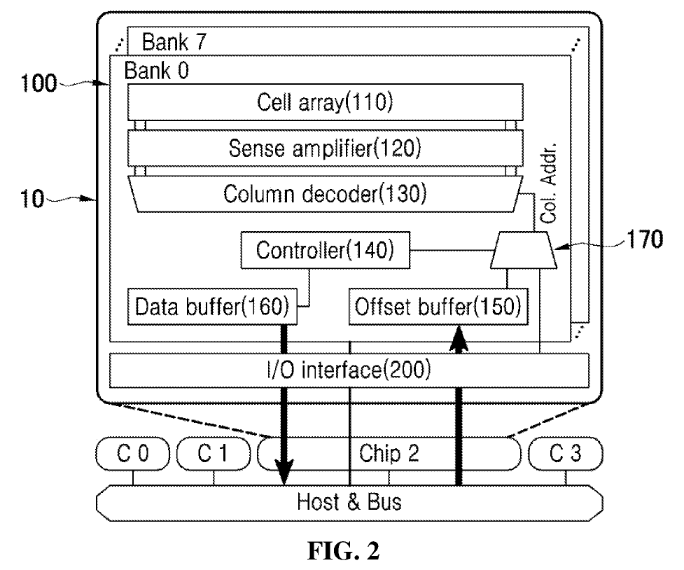

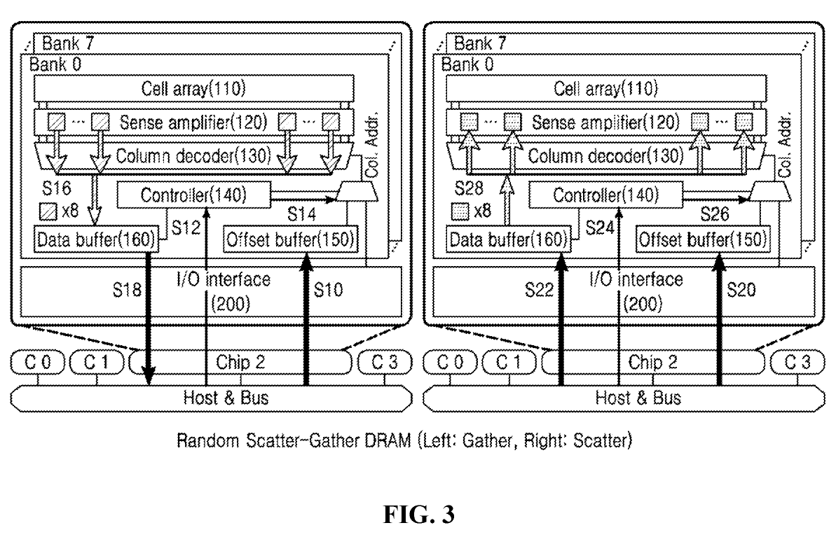

As illustrated in FIG. 2, FIG. 2 shows the configuration of a memory device according to an embodiment of the present invention, and FIG. 3 shows a gather operation and a scatter operation of the memory device according to an embodiment of the present invention.

As shown in FIG. 2, a memory device (10) refers to a memory at the unit of a memory chip, and at least one or more memory banks (100) are included in a single memory device (10). A plurality of memory chips may constitute one DRAM module. In the drawing, it is illustrated that four memory chips (C0 to C4) each include eight memory banks (Bank 0 to Bank 7), but this is merely an example for explanation, and the present invention is not limited thereto.

Each memory bank (100) includes a cell array (110), a sense amplifier (120), a column decoder (130), a controller (140), an offset buffer (150), a data buffer (160), and a multiplexer (MUX) (170). The memory device (10) also includes an I/O interface (200), which performs communication such as data and commands at the memory chip unit including the plurality of memory banks (100).

The memory cell array (110) is an array of a plurality of DRAM memory cells, and may be configured in various forms and sizes. The sense amplifier (120) detects data written in each cell of the memory cell array (110) and is used in the process of reading or writing data. The column decoder (130) decodes a column address transmitted from the offset buffer (150) by the controller (140) and selects a column of the cell to be read or written among the cells included in the memory cell array (110). These components—the memory cell array (110), the sense amplifier (120), and the column decoder (130)—are commonly included in conventional memory, and therefore, detailed operation descriptions thereof will be omitted.

In contrast to conventional technology, the present invention is characterized by further including the controller (140), the offset buffer (150), the data buffer (160), and the multiplexer (170).

The controller (140) executes a read command or a write command for the cell array (110) when a command transmitted from the host or the number of read target addresses or write target addresses stored in the offset buffer (150) is equal to or greater than a threshold.

The offset buffer (150) stores read target addresses or write target addresses transmitted from the host, respectively. When the number of read target addresses or write target addresses reaches the threshold, the controller (140) outputs a plurality of read target addresses or a plurality of write target addresses. The output addresses are transmitted to the column decoder (130) via the multiplexer (170), and the column decoder (130) selects a column of the memory cell corresponding to each read or write target address.

The data buffer (160) temporarily stores data read from each memory cell during the gather operation. When all the number of read data corresponding to the threshold are read, the data are transmitted to the host at once. In the case of the scatter operation, data to be written to each memory cell are temporarily stored in the data buffer (160), and when all the write target data are stored, they are written into the cell array (110) at once.

The I/O interface (200) performs communication between the host and the memory device (10) at the memory chip level, and enables the host to perform gather or scatter operations for each memory bank (100).

Referring to FIG. 3, the gather and scatter operations of the memory device (10) according to the present invention will now be described in detail.

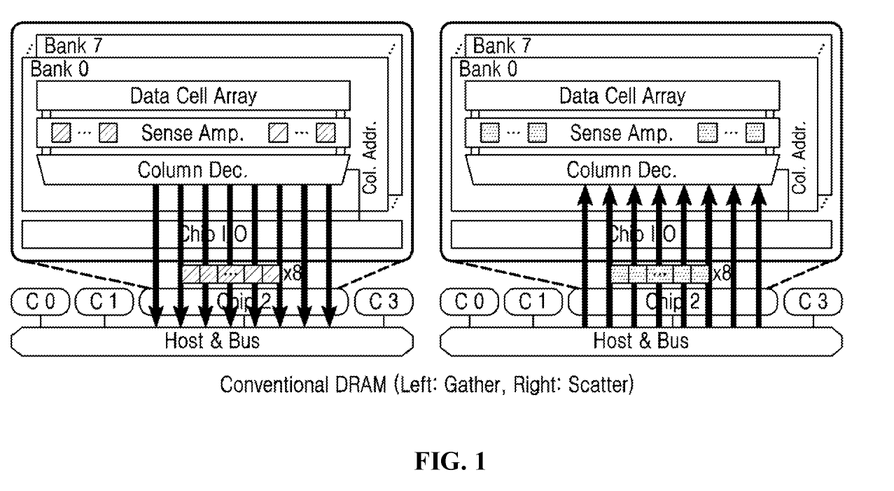

As described in FIG. 1, in conventional technology, a read operation or a write operation is performed on the cell array each time the host transmits a read target address and read command or a write target address and write command. Accordingly, there is a problem of inefficiency caused by frequent access to the cell array.

To solve this problem, the present invention allows the memory controller of the host to store command/address information in the offset buffer (150). When the number of read or write target addresses exceeds a threshold, a read or write operation is executed. As a result, the number of accesses to the memory can be reduced. This significantly increases the memory bandwidth between the host and the memory, theoretically enabling up to four times performance improvement. Additionally, since data moves only inside the memory, the data transfer distance becomes shorter, which helps reduce power consumption of the system.

First, referring to the left side of FIG. 3, the gather operation will be described.

The host transmits a gather command to request reading from multiple locations in the memory. At this time, read target addresses are transmitted to the memory device (10). The read target addresses are sequentially stored in the offset buffer (150) (S10). When the number of read target addresses transmitted to the memory reaches the threshold, the memory controller of the host transmits a command to the controller (140) to start the read operation (S12).

Accordingly, the controller (140) executes a read command for the cell array (110) based on the read target addresses stored in the offset buffer (150) (S14). Specifically, the controller (140) causes the read target addresses stored in the offset buffer (150) to be transmitted to the column decoder (130) via the multiplexer (170), so that the columns of the memory cells corresponding to the read target addresses are selected.

In another embodiment, the controller (140) may directly execute the read command by comparing the number of read target addresses stored in the offset buffer (150) with the threshold, regardless of a command from the host.

According to such an operation of the controller (140), the read data corresponding to the threshold is transferred to the data buffer (160) via the sense amplifier (120). When the data buffer (160) receives all the read data corresponding to the threshold, it transmits the data to the host.

In this way, the present invention allows the entire gather operation to be executed through only one process of transmitting read target addresses from the host to the offset buffer (150), and one process of transmitting read data from the data buffer (160) to the host.

Next, referring to the right side of FIG. 3, the scatter operation will be described.

The host transmits a scatter command requesting writing to multiple locations in the memory. At this time, write target addresses, write target data to be written into the cells, and a write command are transmitted together to the memory device (10). The write target addresses are sequentially stored in the offset buffer (150) (S20). In addition, the write target data to be recorded at the write target addresses are sequentially stored in the data buffer (160) (S22).

When the number of write target addresses transmitted to the memory reaches the threshold and the number of write target data also reaches the threshold, the memory controller of the host transmits a command to the controller (140) to start the write operation (S24).

In response to the command, the controller (140) executes a write command for the cell array (110) based on the write target addresses stored in the offset buffer (150) and the write target data stored in the data buffer (160) (S26). Specifically, the controller (140) transmits the write target addresses stored in the offset buffer (150) to the column decoder (130) via the multiplexer (170), so that the columns corresponding to the write target addresses are selected. Furthermore, the write target data stored in the data buffer (160) are written into the memory cells corresponding to the write target addresses in the cell array (110).

In another embodiment, the controller (140) may directly execute the write command by comparing the number of write target addresses and write target data stored in the offset buffer (150) and the data buffer (160) with the threshold, regardless of a command from the host.

According to the operation of the controller (140) as described above, the number of write data corresponding to the threshold are written into the cell array (110).

As described above, in the present invention, the entire gather operation can be performed with only one transmission process from the host to the offset buffer (150) for the read target addresses, and one transmission process from the data buffer (160) to the host for the read data.

That is, in the conventional technology, in order to read eight pieces of 8-byte data located at random addresses of the memory cell array, eight read commands and addresses must be transmitted, resulting in eight 64-byte read operations. In the case of a scatter operation, similarly, eight write commands and addresses must be transmitted, and eight 64-byte write operations must be performed, leading to unnecessary operations.

However, in the present invention, the eight read target addresses are stored at once in the offset buffer (150), and the resulting eight pieces of read data are transmitted from the data buffer (160) to the host at once. As a result, in the conventional case, the host uses the data bus to access the memory eight times for reading or writing eight data items, whereas in the present invention, the data bus is used only once between the host and the offset buffer (150) and once between the data buffer (160) and the host. Therefore, an ideal fourfold improvement in memory bandwidth can be expected.

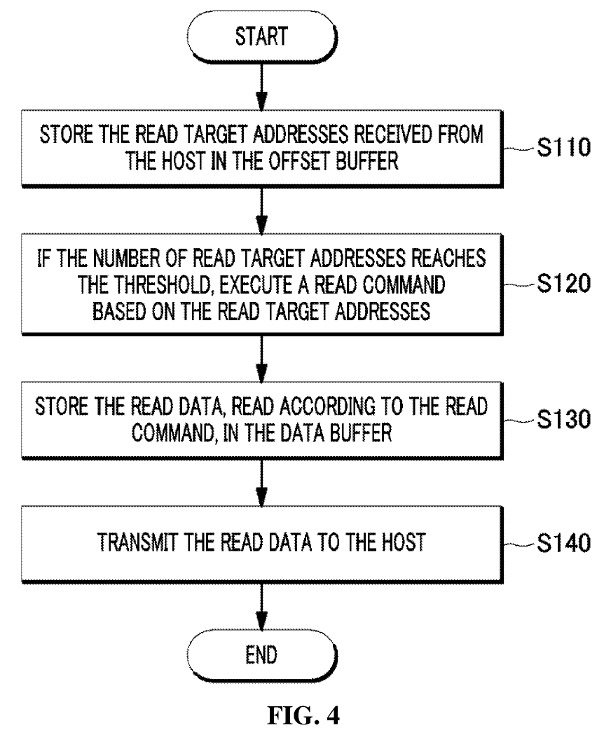

FIG. 4 is a flowchart illustrating a method of operating a memory device to perform a gather operation according to an embodiment of the present invention.

For each memory bank (100) of the memory device (10), read target addresses transmitted from the host are stored in the offset buffer (150) (S110).

Next, when the number of read target addresses reaches the threshold, the controller (140) of the memory device (10) executes a read command for the cell array (110) of the memory device (10) based on the number of read target addresses, in response to the read command transmitted from the host (S120). The read target addresses are transmitted from the offset buffer (150) to the column decoder (130) via the multiplexer (170).

Then, in accordance with the read command, the read data corresponding to the threshold are read from the cell array (110) and stored in the data buffer (160) of the memory device (10) (S130).

Next, the number of read data corresponding to the threshold stored in the data buffer (160) are transmitted to the host (S140).

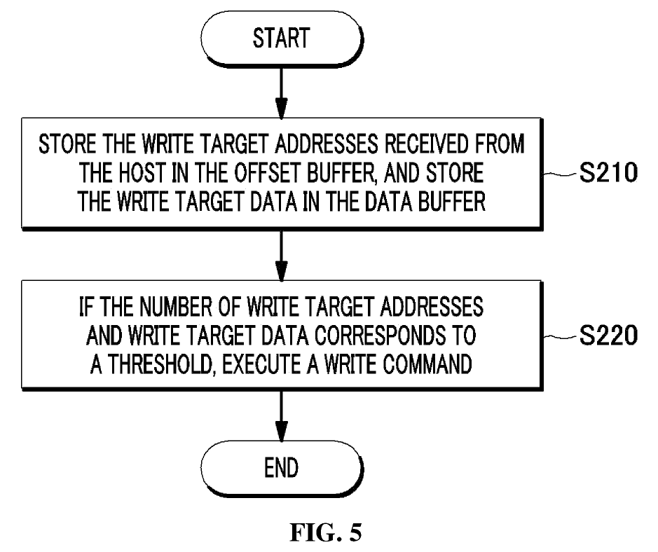

FIG. 5 is a flowchart illustrating a method of operating a memory device to perform a scatter operation according to an embodiment of the present invention.

First, for each memory bank (100) of the memory device (10), write target addresses transmitted from the host are stored in the offset buffer (150), and write target data transmitted from the host are stored in the data buffer (160) (S210).

Next, when the number of write target addresses and the number of write target data reach the threshold, the controller (140) of the memory device (10) executes a write command for the cell array (110) based on the number of write target addresses and the number of write target data, in response to the write command transmitted from the host (S220).

In accordance with the write command, the write target addresses are transmitted from the offset buffer (150) to the column decoder (130) via the multiplexer (170). Also, the write target data are stored into the cell array (110) from the data buffer (160) via the column decoder (130) and the sense amplifier (120).

The method of operating the memory device according to an embodiment of the present invention may also be implemented as a computer-readable medium including executable instructions, such as program modules executed by a computer. The computer-readable medium may be any available medium accessible by a computer, including both volatile and non-volatile media, removable and non-removable media. The computer-readable medium may include a computer storage medium. A computer storage medium includes volatile and non-volatile, removable and non-removable media implemented in any method or technology for storage of information such as computer-readable instructions, data structures, program modules, or other data.

Although the apparatus and method of the present invention have been described in connection with certain embodiments, some or all of their components or operations may be implemented using a computer system having a general-purpose hardware architecture.

The foregoing description of the present invention is illustrative and not intended to be limiting. Those skilled in the art to which the present invention pertains will understand that various modifications and other embodiments may be made without departing from the spirit or essential characteristics of the present invention. Therefore, the embodiments described above are to be regarded as illustrative in all respects and not as restrictive. For example, each component described as being implemented in a single form may be distributed, and likewise, components described as being distributed may be implemented in a combined form.

The scope of the present invention is defined by the following claims rather than by the foregoing detailed description, and all modifications or equivalent substitutions derived from the meaning and scope of the claims are to be construed as being included within the scope of the present invention.

### Description of Reference Numerals

10: Memory device

100: Memory bank

110: Cell array

120: Sense amplifier

130: Column decoder

140: Controller

150: Offset buffer

160: Data buffer

170: Multiplexer (MUX)

200: I/O interface

What is claimed is:

1. A memory device configured to perform a gather operation or a scatter operation,
wherein the memory device comprises at least one memory bank,
wherein the memory bank comprises:
a cell array including a plurality of DRAM memory cells;
an offset buffer in which read target addresses or write target addresses transmitted from a host are stored;
a data buffer in which read data read from the cell array according to the read target addresses, or write data to be stored at the write target addresses, are stored; and
a controller configured to execute a read command or a write command for the cell array when a number of read target addresses or a number of write target addresses in the offset buffer corresponds to a threshold.

2. The memory device of claim 1,
further comprising:
a sense amplifier configured to detect data written in each memory cell of the cell array;
a column decoder configured to decode column addresses of cells included in the cell array; and
a multiplexer configured to transfer the read target addresses or write target addresses stored in the offset buffer to the column decoder in response to execution of the read command or write command by the controller.

3. The memory device of claim 1,
wherein, during a gather operation,
the number of read target addresses corresponding to the threshold are stored in the offset buffer,
the controller executes a read command for the cell array based on the number of read target addresses corresponding to the threshold stored in the offset buffer,
a number of read data corresponding to the threshold, read from the cell array in response to the read command, are stored in the data buffer, and
the number of read data corresponding to the threshold stored in the data buffer are transmitted to the host.

4. The memory device of claim 1,
wherein, during a scatter operation,
the number of write target addresses corresponding to a threshold are stored in the offset buffer,
a number of write target data corresponding to the threshold are stored in the data buffer, and
the controller executes a write command for the cell array based on the number of write target addresses corresponding to the threshold stored in the offset buffer and the number of write target data corresponding to the threshold stored in the data buffer.

5. The memory device of claim 2,
wherein, during a gather operation,
the number of read target addresses corresponding to a threshold are stored in the offset buffer,
the controller executes a read command for the cell array based on the number of read target addresses corresponding to the threshold stored in the offset buffer,
the read target addresses are transmitted to the column decoder through the multiplexer in response to the read command,
a number of read data corresponding to the threshold, read from the cell array through the sense amplifier in response to the read command, are stored in the data buffer, and
the number of read data corresponding to the threshold stored in the data buffer are transmitted to the host.

6. The memory device of claim 2,
wherein, during a scatter operation,
the number of write target addresses corresponding to a threshold are stored in the offset buffer,
a number of write target data corresponding to the threshold are stored in the data buffer,
the controller executes a write command for the cell array based on the number of write target addresses corresponding to the threshold stored in the offset buffer and the number of write target data corresponding to the threshold stored in the data buffer,
the write target addresses are transmitted to the column decoder through the multiplexer in response to the write command, and
the write target data are written into the cell array through the column decoder and the sense amplifier in response to the write command.

7. A method of operating a memory device configured to perform a gather operation,
the method comprising:
storing, in an offset buffer of the memory device, read target addresses transmitted from a host;
executing, by a controller of the memory device, a read command for a cell array of the memory device based on a number of read target addresses corresponding to a threshold, in response to a read command transmitted from the host;
storing, in a data buffer of the memory device, a number of read data corresponding to the threshold and read from the cell array in response to the read command; and
transmitting the number of read data stored in the data buffer to the host.

8. The method of claim 7,
wherein the executing of the read command comprises:
transmitting the read target addresses from the offset buffer to a column decoder of the memory device.

9. A method of operating a memory device configured to perform a scatter operation,
the method comprising:
storing, in an offset buffer of the memory device, write target addresses transmitted from a host, and storing, in a data buffer of the memory device, write target data transmitted from the host; and
executing, by a controller of the memory device, a write command for a cell array of the memory device based on a number of write target addresses and a number of write target data corresponding to a threshold, in response to a write command transmitted from the host.

10. The method of claim 9,
wherein the executing of the write command comprises:
transmitting the write target addresses from the offset buffer to a column decoder of the memory device in response to the write command, and
writing the write target data from the data buffer into the cell array through the column decoder and a sense amplifier in response to the write command.
